(19) United States
(12) Patent Application Publication
(10) Pub. No.: US 2020/0124891 A1
(43) Pub. Date: Apr. 23, 2020

(54) ACTIVE MATRIX SUBSTRATE, LIQUID CRYSTAL DISPLAY PANEL, AND METHOD FOR MANUFACTURING LIQUID CRYSTAL DISPLAY PANEL

(71) Applicant: Sharp Kabushiki Kaisha, Sakai City, Osaka (JP)

(72) Inventor: Toshihisa UCHIDA, Sakai City (JP)

(21) Appl. No.: 16/477,914

(22) PCT Filed: Jan. 11, 2018
(86) PCT No.: PCT/JP2018/000490

§ 371 Date: Jul. 15, 2019

(30) Foreign Application Priority Data
Jan. 16, 2017 (JP) 2017-004878

(51) Int. Cl. G02F 1/1368; H01L 27/12; G02F 1/1333; G02F 1/1345

(52) U.S. Cl. CPC G02F 1/1368; H01L 27/1225; H01L 27/1251; G02F 1/136227; G02F 1/133345; G02F 1/13454; G02F 2001/13685; G02F 1/133351

(57) ABSTRACT

An active matrix substrate includes: a substrate; TFTs supported on the substrate; and an inorganic insulating layer which covers the TFTs. Each TFT includes a gate electrode provided on the substrate, a gate insulating layer which covers the gate electrode, an oxide semiconductor layer provided on the gate insulating layer, and a source electrode and a drain electrode connected to the oxide semiconductor layer. The gate insulating layer includes a first silicon nitride layer and a first silicon oxide layer which is provided on the first silicon nitride layer. The inorganic insulating layer includes a second silicon oxide layer and a second silicon nitride layer which is provided on the second silicon oxide layer. The first silicon nitride layer, the first silicon oxide layer, the second silicon oxide layer, and the second silicon nitride layer have thicknesses which are respectively not less than 275 nm and not more than 400 nm, not less than 20 nm and not more than 80 nm, not less than 200 nm and not more than 300 nm, and not less than 100 nm and not more than 200 nm.

### TECHNICAL FIELD

The present invention relates to an active matrix substrate, and more particularly to an active matrix substrate that includes oxide semiconductor TFTs. The present invention also relates to a liquid crystal display panel that includes such an active matrix substrate, and a method of producing the same.

### BACKGROUND ART

Active matrix substrates that are used for liquid crystal display devices or the like include a switching element for each pixel, e.g., a thin film transistor (hereinafter “TFT”). As such switching elements, TFTs whose active layer is an amorphous silicon film (hereinafter “amorphous silicon TFTs”) and TFTs whose active layer is a polycrystalline silicon film (hereinafter “polycrystalline silicon TFTs”) have been widely used.

In the recent years, it has been proposed to use an oxide semiconductor as the material of the active layers of TFTs, instead of an amorphous silicon or a polycrystalline silicon. These TFTs are called “oxide semiconductor TFTs”. Patent Document 1 discloses an active matrix substrate in which an In—Ga—Zn—O based semiconductor film is used for the active layers of TFTs.

An oxide semiconductor provides a higher mobility than does an amorphous silicon. Therefore, oxide semiconductor TFTs can operate more rapidly than amorphous silicon TFTs. Moreover, an oxide semiconductor film is formed through a simple process as compared to a polycrystalline silicon film, and therefore is applicable to devices which require a large geometric area.

Patent Document 2 discloses a construction where an inorganic insulating layer covering a bottom-gate type oxide semiconductor TFT has a multilayer structure. Specifically, this inorganic insulating layer includes a silicon oxide layer on a lower layer side and a silicon nitride layer on an upper layer side, such that the silicon nitride layer has a thickness of 35 nm to 75 nm. Patent Document 2 states that such construction will suppress insufficient operations of oxide semiconductor TFTs which are disposed in the non-displaying section.

Patent Document 2 also discloses a construction where a gate insulating layer covering gate electrodes has a multilayer structure. Specifically, a construction in which the gate insulating layer includes a silicon nitride layer on a lower layer side and a silicon oxide layer on an upper layer side is disclosed.

### CITATION LIST

### Patent Literature

[Patent Document 1] Japanese Laid-Open Patent Publication No. 2012-134475

[Patent Document 2] International Publication No. 2014/080826

### SUMMARY OF INVENTION

### Technical Problem

However, it has been found through a study by the inventor that, when an inorganic insulating layer and a gate insulating layer have the aforementioned multilayer structure, variations in coloration may occur within the plane of the mother substrate. This is because in-plane variations in the thickness of the respective layer (insulating layer) constituting each of the inorganic insulating layer and the gate insulating layer are perceived as differences in interference colors (due to optical interference among a plurality of insulating layers). When actually providing a liquid crystal display panel, it is very difficult to avoid variations in the thickness of an insulating layer within the plane of the mother substrate. In recent years, the mother glass (mother substrate) has been increasing in size, this being in order to increase the number of daughter substrates (i.e., the number of substrates that are available from one mother glass piece). The aforementioned variations in coloration will become more noticeable as the size of the mother substrate increases.

A liquid crystal display panel which was produced by cutting a mother substrate that had significant variation in coloration within the plane will have significant variation in coloration from panel to panel, and/or within the panel plane. The thickness range (35 nm to 75 nm) of the silicon nitride layer in the inorganic insulating layer as disclosed in Patent Document 2 is chosen in favor of the electrical properties of the oxide semiconductor TFT, and is not able to suppress the aforementioned variations in coloration.

The present invention has been made in view of the above problems, and an objective thereof is to suppress variations in coloration when producing a liquid crystal display panel that includes an active matrix substrate which includes: oxide semiconductor TFTs; and a gate insulating layer and an inorganic insulating layer each having a multilayer structure.

### Solution to Problem

An active matrix substrate according to an embodiment of the present invention is an active matrix substrate comprising: a substrate; a plurality of thin film transistors supported on the substrate; and an inorganic insulating layer which covers the plurality of thin film transistors, wherein, each of the plurality of thin film transistors includes a gate electrode provided on the substrate, a gate insulating layer which covers the gate electrode, an oxide semiconductor layer being provided on the gate insulating layer and opposed to the gate electrode via the gate insulating layer, and a source electrode and a drain electrode which are electrically connected to the oxide semiconductor layer; the gate insulating layer includes a first silicon nitride layer and a first silicon oxide layer which is provided on the first silicon nitride layer; the inorganic insulating layer includes a second silicon oxide layer and a second silicon nitride layer which is provided on the second silicon oxide layer; the first silicon nitride layer has a thickness which is not less than 275 nm and not more than 400 nm; the first silicon oxide layer has a thickness which is not less than 20 nm and not more than 80 nm; the second silicon oxide layer has a thickness which is not less than 200 nm and not more than 300 nm; and the second silicon nitride layer has a thickness which is not less than 100 nm and not more than 200 nm.

In one embodiment, the oxide semiconductor layer comprises an In—Ga—Zn—O based semiconductor.

In one embodiment, the In—Ga—Zn—O based semiconductor includes a crystalline portion.

In one embodiment, the active matrix substrate comprises a further thin film transistor that includes a crystalline silicon semiconductor layer as an active layer.

In one embodiment, the further thin film transistor includes: the crystalline silicon semiconductor layer provided on the substrate; a further gate insulating layer which covers the crystalline silicon semiconductor layer; a further gate electrode being provided on the further gate insulating layer and opposed to the crystalline silicon semiconductor layer via the further gate insulating layer; and a further source electrode and a further drain electrode which are electrically connected to the crystalline silicon semiconductor layer.

In one embodiment, the further gate electrode is covered by the gate insulating layer; the further gate insulating layer includes a third silicon nitride layer; and a total of a thickness of the first silicon nitride layer of the gate insulating layer and a thickness of the third silicon nitride layer of the further gate insulating layer is not less than 275 nm and not more than 400 nm.

A liquid crystal display panel according to an embodiment of the present invention comprises: an active matrix substrate having the above construction; a counter substrate opposed to the active matrix substrate; and a liquid crystal layer provided between the active matrix substrate and the counter substrate.

A method of producing a liquid crystal display panel according to an embodiment of the present invention is a method of producing a liquid crystal display panel that includes an active matrix substrate having a substrate and a plurality of thin film transistors supported on the substrate, a counter substrate opposed to the active matrix substrate, and a liquid crystal layer provided between the active matrix substrate and the counter substrate, the method comprising: step (A) of providing a first mother substrate including a plurality of said active matrix substrates; step (B) of providing a second mother substrate including a plurality of said counter substrates; step (C) of producing a mother panel by attaching together the first mother substrate and the second mother substrate, the mother panel including a plurality of said liquid crystal display panels; and step (D) of obtaining the liquid crystal display panel by cutting apart the mother panel, wherein, step (A) of providing the first mother substrate comprises step (a) of providing an electrically-insulative substrate of a size accommodating a plurality of said substrates, step (b) of forming gate electrodes on the electrically-insulative substrate, for each region corresponding to the substrate, step (c) of forming a gate insulating layer which covers the gate electrodes, step (d) of forming an oxide semiconductor layer on the gate insulating layer, the oxide semiconductor layer being opposed to the gate electrodes via the gate insulating layer, step (e) of forming source electrodes and drain electrodes which are electrically connected to the oxide semiconductor layer, and step (f) of forming an inorganic insulating layer which covers the oxide semiconductor layer, the source electrodes, and the drain electrodes; step (c) comprises step (c-1) of forming a first silicon nitride layer which covers the gate electrodes, and step (c-2) of forming a first silicon oxide layer on the first silicon nitride layer; step (f) comprises step (f-1) of forming a second silicon oxide layer which covers the oxide semiconductor layer, the source electrodes, and the drain electrodes, and step (f-2) of forming a second silicon nitride layer on the second silicon oxide layer; the electrically-insulative substrate to be provided in step (a) is sized so that a length thereof along a longitudinal direction is 1800 mm or more; and, when variation in chromaticity (u′, v′) within a plane of the first mother substrate that is caused by an interference of light associated with the first silicon nitride layer, the first silicon oxide layer, the second silicon oxide layer, and the second silicon nitride layer is expressed by a difference du′ between a largest u′ and a smallest u′ and a difference dv′ between a largest v′ and a smallest v′, steps (c-1), (c-2), (f-1), and (f-2) are performed while setting thicknesses of the first silicon nitride layer, the first silicon oxide layer, the second silicon oxide layer, and the second silicon nitride layer so that du′<0.008 and dv′<0.010.

In one embodiment, in step (c-1), the first silicon nitride layer is formed with a thickness which is not less than 275 nm and not more than 400 nm; in step (c-2), the first silicon oxide layer is formed with a thickness which is not less than 20 nm and not more than 80 nm; in step (f-1), the second silicon oxide layer is formed with a thickness which is not less than 200 nm and not more than 300 nm; and in step (f-2), the second silicon nitride layer is formed with a thickness which is not less than 100 nm and not more than 200 nm.

In one embodiment, the oxide semiconductor layer comprises an In—Ga—Zn—O based semiconductor.

In one embodiment, the In—Ga—Zn—O based semiconductor includes a crystalline portion.

### Advantageous Effects of Invention

According to an embodiment of the present invention, it is possible to suppress variations in coloration when producing a liquid crystal display panel that includes an active matrix substrate which includes: oxide semiconductor TFTs; and a gate insulating layer and an inorganic insulating layer each having a multilayer structure.

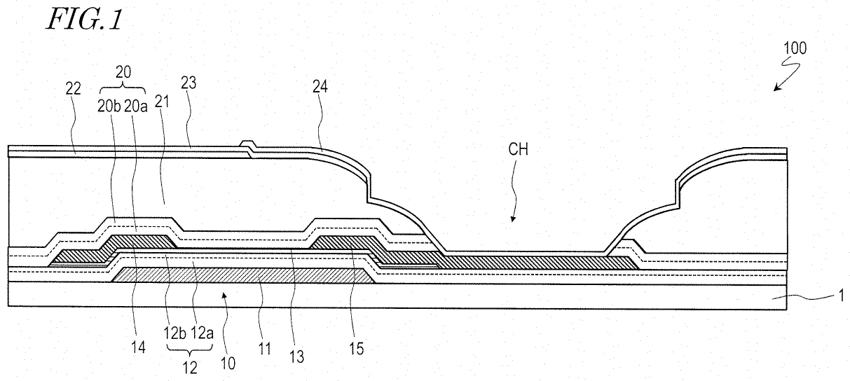

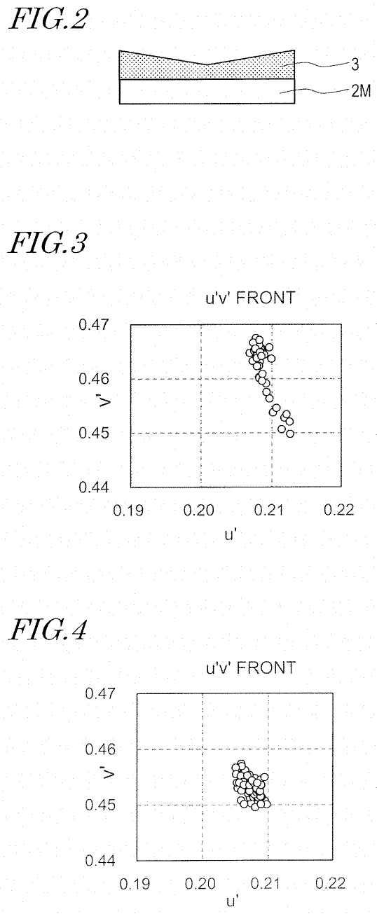

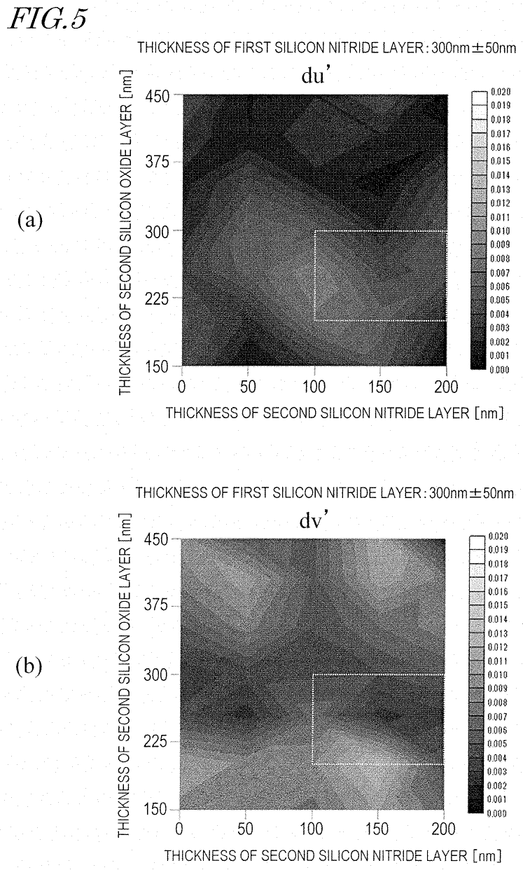

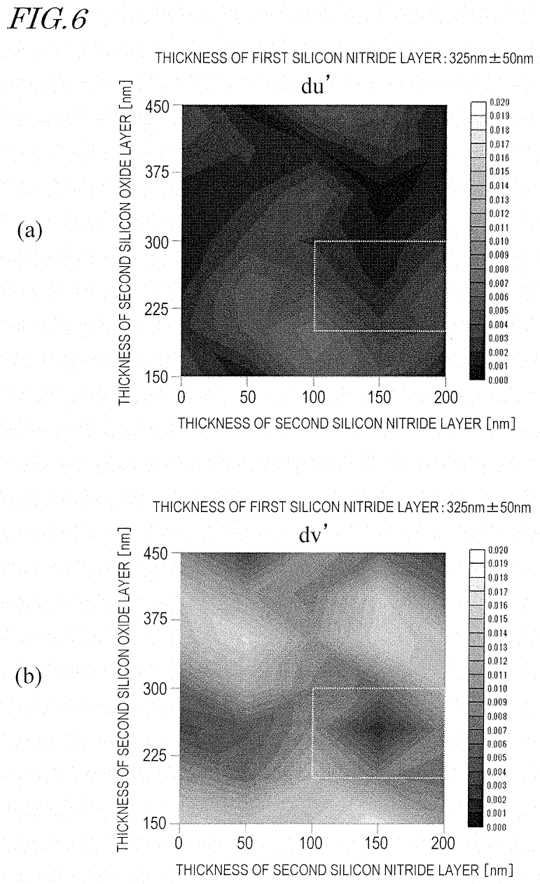

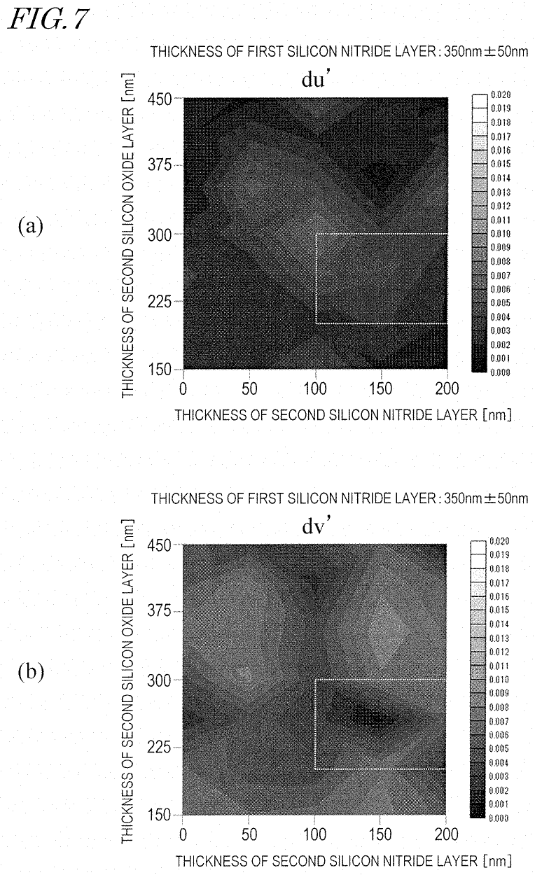

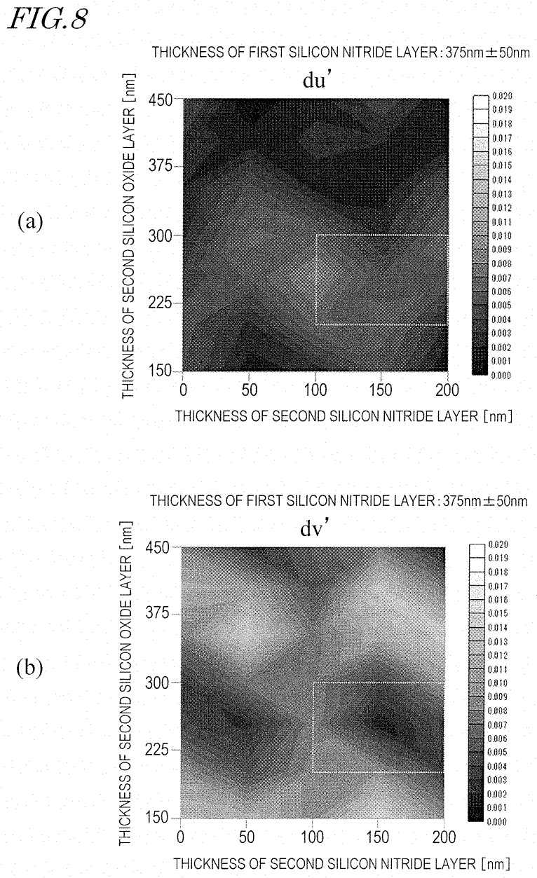

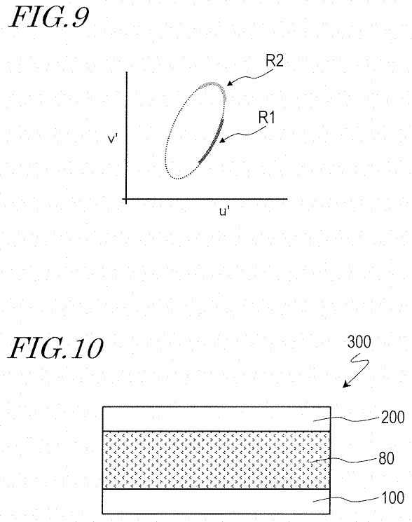

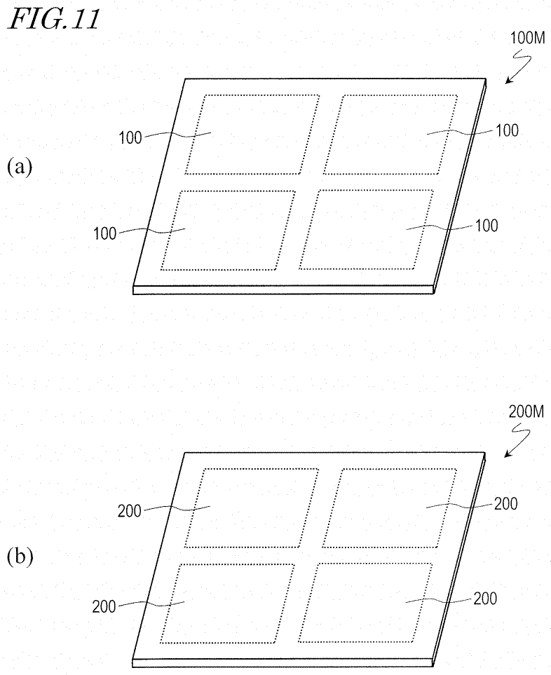

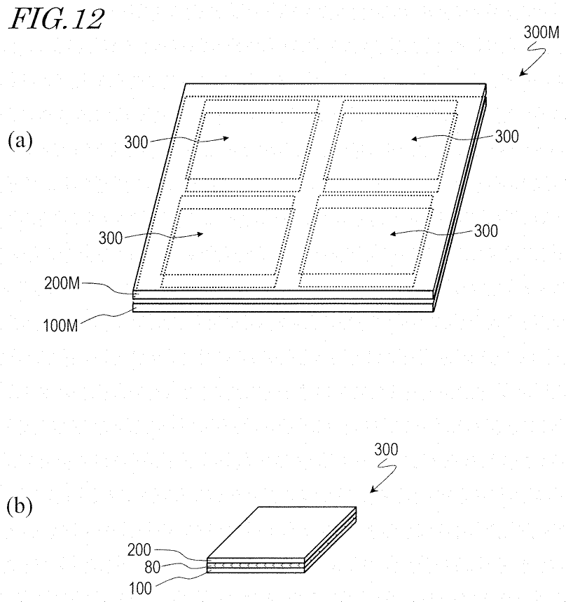

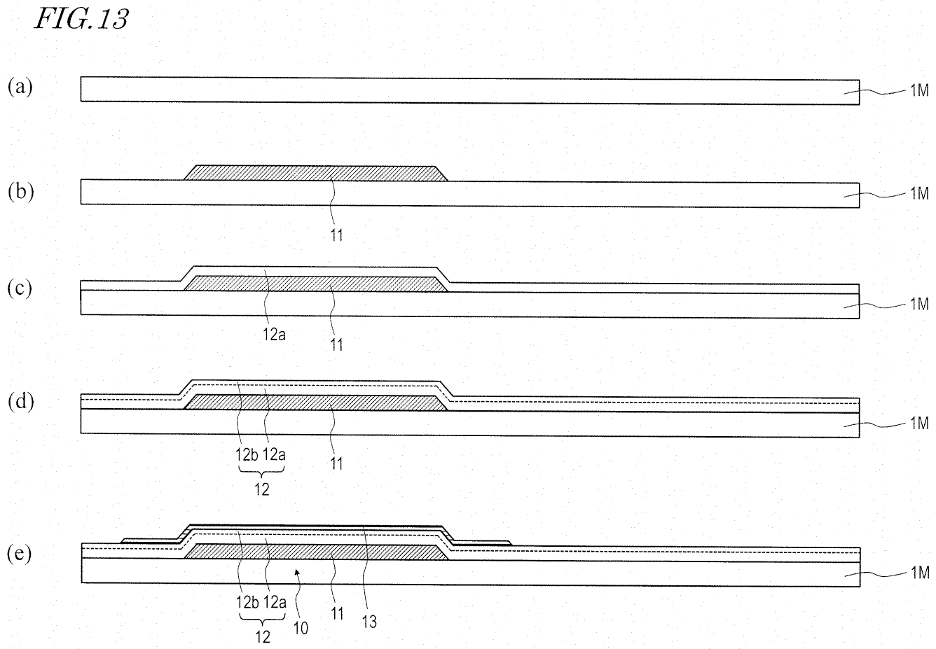

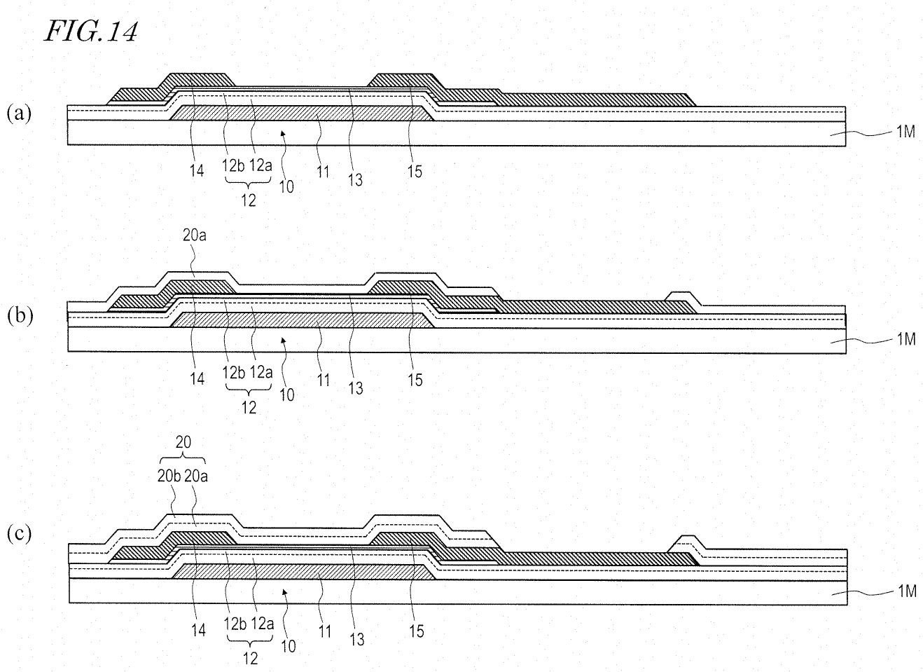

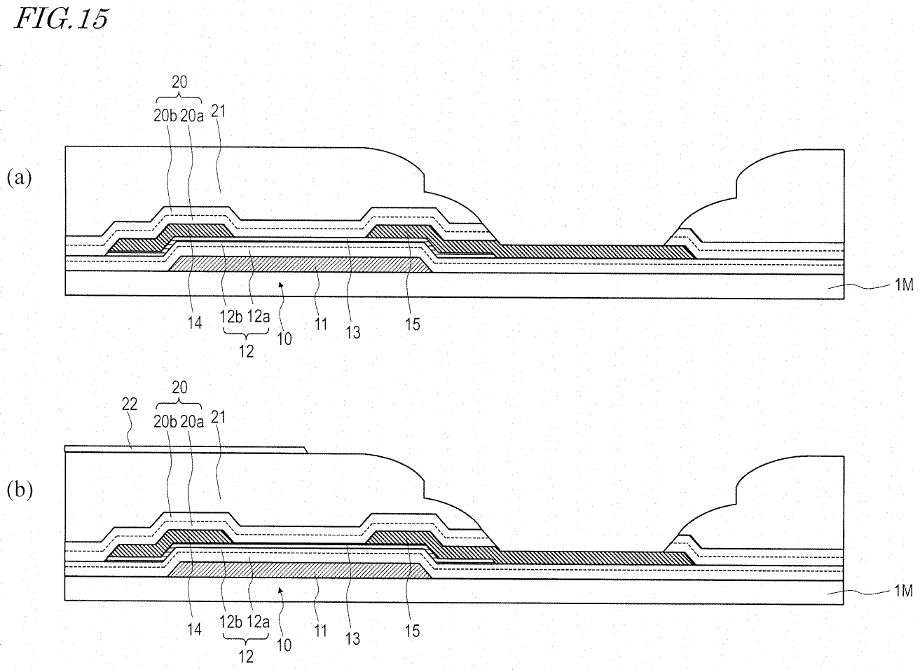

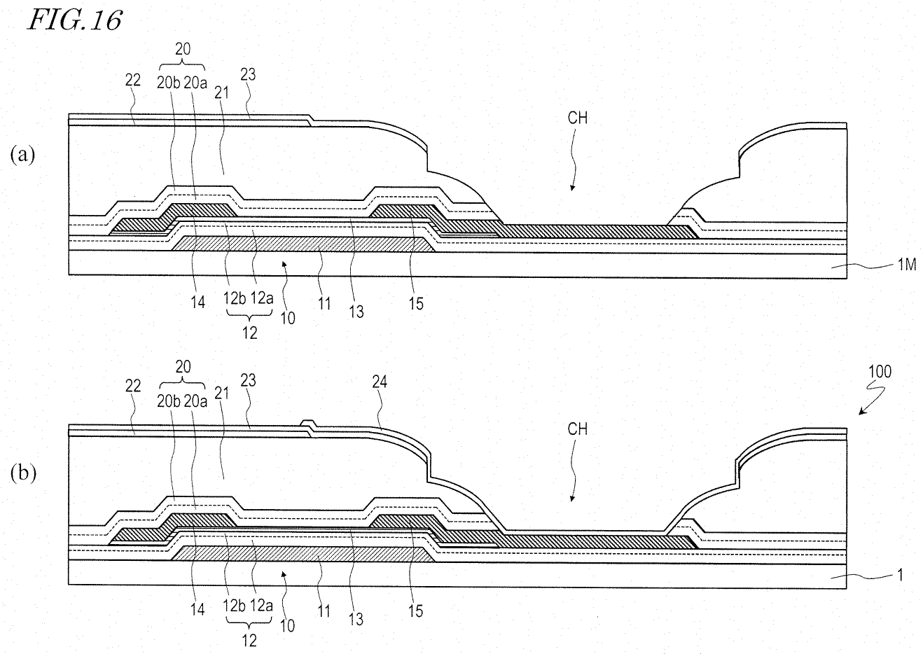

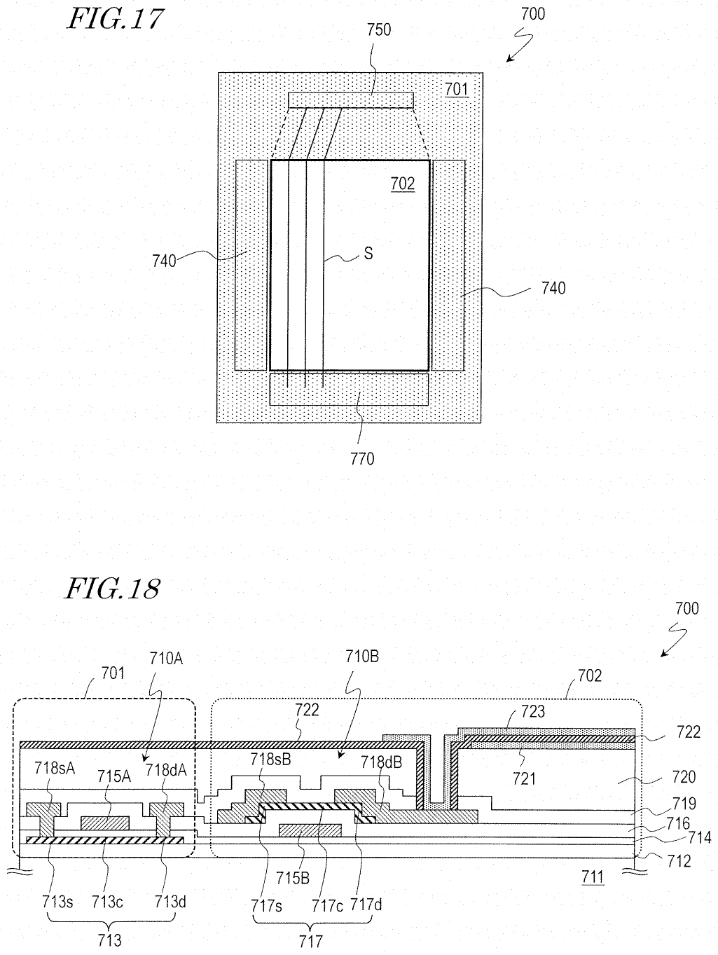

### BRIEF DESCRIPTION OF DRAWINGS

[FIG. 1] A cross-sectional view schematically showing an active matrix substrate 100 according to an embodiment of the present invention.

[FIG. 2] A diagram showing how an insulating layer 3 which is formed on a mother substrate 2M may have variation in thickness.

[FIG. 3] A u′v′ chromaticity diagram showing a chromaticity distribution when a mother substrate according to Comparative Example is observed from the frontal direction.

[FIG. 4] A u′v′ chromaticity diagram showing a chromaticity distribution when a mother substrate according to Example is observed from the frontal direction.

[FIG. 5](a) and (b) are graphs showing levels of du′ and dv′ in grayscale, where a first silicon nitride layer 12a fluctuates in thickness by ±50 nm from 300 nm, the horizontal axis representing the thickness of a second silicon nitride layer 20b and the vertical axis representing the thickness of a second silicon oxide layer 20a.

[FIG. 6](a) and (b) are graphs showing levels of du′ and dv′ in grayscale, where the first silicon nitride layer 12a fluctuates in thickness by ±50 nm from 325 nm, the horizontal axis representing the thickness of the second silicon nitride layer 20b and the vertical axis representing the thickness of the second silicon oxide layer 20a.

[FIG. 7](a) and (b) are graphs showing levels of du′ and dv′ in grayscale, where the first silicon nitride layer 12a fluctuates in thickness by ±50 nm from 350 nm, the horizontal axis representing the thickness of the second silicon nitride layer 20b and the vertical axis representing the thickness of the second silicon oxide layer 20a.

[FIG. 8](a) and (b) are graphs showing levels of du′ and dv′ in grayscale, where the first silicon nitride layer 12a fluctuates in thickness by ±50 nm from 375 nm, the horizontal axis representing the thickness of the second silicon nitride layer 20b and the vertical axis representing the thickness of the second silicon oxide layer 20a.

[FIG. 9] A chromaticity diagram schematically showing changes in interference colors associated with fluctuations in the layer thicknesses of a gate insulating layer and an inorganic insulating layer.

[FIG. 10] A cross-sectional view schematically showing a liquid crystal display panel 300 that includes the active matrix substrate 100 according to an embodiment of the present invention.

[FIG. 11](a) and (b) are perspective views schematically showing production steps of the liquid crystal display panel 300.

[FIG. 12](a) and (b) are perspective views schematically showing production steps of the liquid crystal display panel 300.

[FIG. 13](a) through (e) are cross-sectional views schematically showing production steps of the first mother substrate 100M.

[FIG. 14](a) through (c) are cross-sectional views schematically showing production steps of the first mother substrate 100M.

[FIG. 15](a) and (b) are cross-sectional views schematically showing production steps of the first mother substrate 100M.

[FIG. 16](a) and (b) are cross-sectional views schematically showing production steps of the first mother substrate 100M.

[FIG. 17] A schematic plan view showing an exemplary planar structure of an active matrix substrate 700 according to an embodiment of the present invention.

[FIG. 18] A cross-sectional view of a crystalline silicon TFT 710A and an oxide semiconductor TFT 710B in an active matrix substrate 700.

### DESCRIPTION OF EMBODIMENTS

Hereinafter, with reference to the drawings, embodiments of the present invention will be described. Note that the present invention is not limited to the following embodiments.

### Embodiment 1

With reference to FIG. 1, an active matrix substrate 100 according to the present embodiment will be described. FIG. 1 is a cross-sectional view schematically showing the active matrix substrate 100. The active matrix substrate 100 illustrated in FIG. 1 represents that which is used in a liquid crystal display panel of the FFS (Fringe Field Switching) mode.

As shown in FIG. 1, the active matrix substrate 100 includes a substrate 1, a plurality of thin film transistors (TFTs) 10 supported on the substrate 1, and an inorganic insulating layer 20 covering the plurality of thin film transistors 10. FIG. 1 shows a region corresponding to one pixel of the liquid crystal display panel, illustrating a TFT that is provided in each pixel. The active matrix substrate 100 further includes an organic insulating layer 21, a common electrode 22, a dielectric layer 23, and pixel electrodes 24.

The substrate 1 is a transparent substrate which is electrically insulative. The substrate 1 may be a glass substrate, for example.

Each of the plurality of TFTs 10 includes a gate electrode 11, a gate insulating layer 12, an oxide semiconductor layer 13, a source electrode 14, and a drain electrode 15. In other words, the TFT 10 is an oxide semiconductor TFT.

The gate electrode 11 is provided on the substrate 1. The gate electrode 11 is electrically connected to a scanning line (gate line) not shown, so that a scanning signal (gate signal) is supplied thereto from the scanning line.

The gate insulating layer 12 covers the gate electrode 11. In the present embodiment, the gate insulating layer 12 includes a silicon nitride (SiNₓ) layer 12a and a silicon oxide (SiO₂) layer 12b which is provided on the silicon nitride layer 12a. In other words, the gate insulating layer 12 has a multilayer structure in which the silicon nitride layer 12a is provided in a lower layer and the silicon oxide layer 12b is provided in an upper layer. By providing the silicon oxide layer 12b at the upper layer side that is in contact with the oxide semiconductor layer 13, oxygen deficiencies in the oxide semiconductor layer 13 can be prevented.

The oxide semiconductor layer 13 is provided on the gate insulating layer 12. The oxide semiconductor layer 13 is opposed to the gate electrode 11 via the gate insulating layer 12.

The source electrode 14 and the drain electrode 15 are electrically connected to the oxide semiconductor layer 13. The source electrode 14 is electrically connected to a signal line (source line) not shown, so that a display signal (source signal) is supplied thereto from the signal line. Moreover, the drain electrode 15 is electrically connected to the pixel electrode 24.

The inorganic insulating layer (passivation film) covers the oxide semiconductor layer 13, the source electrode 14, and the drain electrode 15. In the present embodiment, the inorganic insulating layer 20 includes a silicon oxide (SiO₂) layer 20a and a silicon nitride (SiNₓ) layer 20b which is provided on the silicon oxide layer 20a. In other words, the inorganic insulating layer 20 has a multilayer structure in which the silicon oxide layer 20a is provided in a lower layer and the silicon nitride layer 20b is provided in an upper layer. By providing the silicon oxide layer 20a at the lower layer side that is in contact with the oxide semiconductor layer 13, oxygen deficiencies in the oxide semiconductor layer 13 can be prevented.

The organic insulating layer (planarization film) 21 is provided on the inorganic insulating layer 20. The organic insulating layer 21 may be made of a photosensitive resin material, for example.

The common electrode 22 is provided on the organic insulating layer 21. The common electrode 22 is a single electrically conductive film that is formed across the entire display region, and is given a common potential across the plurality of pixels. The common electrode 22 is made of a transparent electrically conductive material (e.g., ITO or IZO).

The dielectric layer 23 is provided so as to cover the common electrode 22. The dielectric layer 23 may be a silicon nitride layer, for example.

On the dielectric layer 23, the pixel electrode 24 is provided for each pixel. The pixel electrode 24 is made of a transparent electrically conductive material (e.g., ITO or IZO). In a contact hole CH that is made in the inorganic insulating layer 20, in the organic insulating layer 21, and in the dielectric layer 23, the pixel electrode 24 is connected to the drain electrode 15 of the TFT 10. Although not shown herein, at least one slit is made in the pixel electrode 24.

As described above, in the present embodiment, the gate insulating layer 12 and the inorganic insulating layer each have a multilayer structure. Hereinafter, the silicon nitride layer 12a and the silicon oxide layer 12b of the gate insulating layer 12 may respectively be referred to as the “first silicon nitride layer” and the “first silicon oxide layer”, whereas the silicon oxide layer 20a and the silicon nitride layer 20b of the inorganic insulating layer 20 my respectively be referred to as the “second silicon oxide layer” and the “second silicon nitride layer”.

In the active matrix substrate 100 of the present embodiment, the first silicon nitride layer 12a, the first silicon oxide layer 12b, the second silicon oxide layer 20a, and the second silicon nitride layer 20b each have a thickness within a specific range. Specifically, as shown in in Table 1 below, the thickness of the first silicon nitride layer 12a is not less than 275 nm and not more than 400 nm, while the thickness of the first silicon oxide layer 12b is not less than 20 nm and not more than 80 nm. Moreover, the thickness of the second silicon oxide layer 20a is not less than 200 nm and not more than 300 nm, while the thickness of the second silicon nitride layer 20b is not less than 100 nm and not more than 200 nm.

TABLE 1

| | | thickness |
|---|---|---|
| gate insulating | first silicon | not less than 275 nm |
| layer | nitride layer | & not more than 400 nm |
| | first silicon | not less than 20 nm |
| | oxide layer | & not more than 80 nm |
| inorganic | second silicon | not less than 200 nm |
| insulating layer | oxide layer | & not more than 300 nm |
| (passivation | second silicon | not less than 100 nm |
| layer) | nitride layer | & not more than 200 nm |

In the case where the thicknesses of the first silicon nitride layer 12a and the first silicon oxide layer 12b constituting the gate insulating layer 12 are set in the ranges indicated in Table 1, variations in coloration due to differences in interference colors can be suppressed by setting the thicknesses of the second silicon oxide layer 20a and the second silicon nitride layer 20b constituting the inorganic insulating layer 20 in the ranges indicated in Table 1. Hereinafter, the reason thereof will be described in more detail.

Any insulating layer (a silicon nitride layer or a silicon oxide layer) that is formed on a mother substrate by CVD technique, sputtering technique, etc., will have some variation in thickness within the plane of the mother substrate. Typically, as schematically shown in FIG. 2, the thickness of the insulating layer 3 increases toward the outer periphery and away from the center of the mother substrate 2M. Therefore, as the mother substrate 2M increases in size, the in-plane variation in the thickness of the insulating layer 3 will increase. Therefore, as the mother substrate 2M increases in size, the mother substrate 2M will have greater variations in coloration within the plane. According to a study by the inventor, specifically, variations in coloration were noticeable when a longer side of the mother substrate 2M had a length (i.e., a length along its longitudinal direction) which was 1800 mm or greater.

FIG. 3 shows, regarding a mother substrate (Comparative Example) which was produced by setting the gate insulating layer 12 and the inorganic insulating layer 20 to thicknesses as indicated in Table 2 below, a chromaticity distribution within the plane of the mother substrate. FIG. 3 shows chromaticity (u′, v′) in the case where the mother substrate according to Comparative Example was observed from the frontal direction.

TABLE 2
Comparative Example

| | | thickness |
|---|---|---|
| gate insulating | first silicon | 325 nm |
| layer | nitride layer | |
| | first silicon | 50 nm |
| | oxide layer | |
| inorganic | second silicon | 335 nm |
| insulating layer | oxide layer | |
| (passivation | second silicon | 50 nm |
| layer) | nitride layer | |

As shown in Table 2, in Comparative Example, the thickness of the gate insulating layer 12 is within the range indicated in Table 1, but the thickness of the inorganic insulating layer 20 is not within the range indicated in Table 1. It can be seen from FIG. 3 that the mother substrate of Comparative Example has significant variations in chromaticity, with particularly noticeable variations occurring in v′.

FIG. 4 shows, regarding a mother substrate (Example) which was produced by setting the gate insulating layer 12 and the inorganic insulating layer 20 to thicknesses as indicated in Table 3 below, a chromaticity distribution within the plane of the mother substrate. FIG. 4 shows chromaticity (u′, v′) in the case where the mother substrate according to Example was observed from the frontal direction.

TABLE 3
Comparative Example

| | | thickness |
|---|---|---|
| gate insulating | first silicon | 350 nm |
| layer | nitride layer | |
| | first silicon | 50 nm |
| | oxide layer | |
| inorganic | second silicon | 270 nm |
| insulating layer | oxide layer | |
| (passivation | second silicon | 150 nm |
| layer) | nitride layer | |

As shown in Table 3, in Example, the thickness of the gate insulating layer 12 is in the range indicated in Table 1, and the thickness of the inorganic insulating layer 20 is also in the range indicated in Table 1. It can be seen from FIG. 4 that the mother substrate of Example has small variations in chromaticity, such that variations in v′ are remarkably suppressed.

Now, with reference to FIG. 5 to FIG. 8, a simulation result of studying a thickness of the inorganic insulating layer 20 that allows variations in chromaticity to be suppressed will be described. In the following description, any variation in chromaticity (u′, v′) within the plane of the mother substrate that is caused by an interference of light associated with the first silicon nitride layer 12a, the first silicon oxide layer 12b, the second silicon oxide layer 20a, and the second silicon nitride layer 20b is expressed by a difference du′ between a largest u′ and a smallest u′ and a difference dv′ between a largest v′ and a smallest v′. In the study, the refractive indices of the first silicon nitride layer 12a, the first silicon oxide layer 12b, the second silicon oxide layer 20a, and the second silicon nitride layer 20b were respectively about 1.9, about 1.4, about 1.4, and about 1.8.

FIGS. 5(a) and (b), FIGS. 6(a) and (b), FIGS. 7(a) and (b), and FIGS. 8(a) and (b) are graphs showing levels of du′ and dv′ in grayscale, where the horizontal axis represents the thickness of the second silicon nitride layer 20b and the vertical axis represents the thickness of the second silicon oxide layer 20a. FIGS. 5(a) and (b) show du′ and dv′ in the case where the first silicon nitride layer 12a fluctuates in thickness by ±50 nm from 300 nm, whereas FIGS. 6(a) and (b) show du′ and dv′ in the case where the first silicon nitride layer 12a fluctuates in thickness by ±50 nm from 325 nm. Moreover, FIGS. 7(a) and (b) show du′ and dv′ in the case where the first silicon nitride layer 12a fluctuates in thickness by ±50 nm from 350 nm, whereas FIGS. 8(a) and (b) show du′ and dv′ in the case where the first silicon nitride layer 12a fluctuates in thickness by ±50 nm from 375 nm.

As shown in FIG. 5, FIG. 6, FIG. 7, and FIG. 8, both of du′ and dv′ are relatively small within a range where the thickness of the second silicon oxide layer 20a is not less than 250 nm and not more than 300 nm and the thickness of the second silicon nitride layer 20b is not less than 100 nm and not more than 200 nm (i.e., a region surrounded by a dotted line in the figures). It can be seen from this that, when the thicknesses of the gate insulating layer 12 (i.e., the first silicon nitride layer 12a and the first silicon oxide layer 12b) and the inorganic insulating layer (i.e., the second silicon oxide layer 20a and the second silicon nitride layer 20b) are set in the ranges indicated in Table 1, variations in coloration due to differences in interference colors can be suppressed.

The reason why variations in coloration are suppressed may also be explained as follows. The inventor has analyzed the change in interference colors associated with fluctuations in layer thickness, thus finding that, as schematically shown in FIG. 9, interference colors tend to present an ellipse on the chromaticity diagram. For this reason it can be said that the aforementioned effects are being obtained by setting the thicknesses of the gate insulating layer 12 and the inorganic insulating layer 20 so as to correspond to a region where there is relatively little change in interference colors associated with fluctuations in layer thickness (e.g., region R2 in FIG. 9), rather than to a region where there is large change in interference colors associated with fluctuations in layer thickness (e.g., region R1 in FIG. 9).

Thus, according to an embodiment of the present invention, it is possible to suppress variations in coloration when producing a liquid crystal display panel that includes an active matrix substrate which includes: oxide semiconductor TFTs; and a gate insulating layer and an inorganic insulating layer each having a multilayer structure.

FIG. 1 illustrates an exemplary arrangement where the pixel electrode 24 is disposed on the common electrode 22 via the dielectric layer 23. Contrary to this, the common electrode 22 may be disposed on the pixel electrode 24 via the dielectric layer 23. In that case, at least one slit is to be formed in the common electrode 22.

Although the present embodiment illustrates an active matrix substrate 100 for a liquid crystal display panel of the FFS mode as an example, embodiments of the present invention are also suitably used in active matrix substrates of liquid crystal display panels of other display modes (e.g., TN (Twisted Nematic) and VA (Vertical Alignment) modes).

[Liquid Crystal Display Panel and Method of Producing the Same]

FIG. 10 shows a liquid crystal display panel 300 that includes an active matrix substrate 100 according to an embodiment of the present invention. As shown in FIG. 10, the liquid crystal display panel 300 includes: an active matrix substrate 100, a counter substrate 200 which is opposed to the active matrix substrate 100, and a liquid crystal layer 80 provided between the active matrix substrate 100 and the counter substrate 200.

The active matrix substrate 100 may be adapted to the FFS mode as illustrated above, or adapted to any other display mode. The active matrix substrate 100 includes an oxide semiconductor TFT 10 and a pixel electrode 24 that are provided for each pixel. A gate insulating layer 12 of the oxide semiconductor TFT 10 has a multilayer structure including a first silicon nitride layer 12a and a first silicon oxide layer 12b. An inorganic insulating layer 20 covering the oxide semiconductor TFT 10 has a multilayer structure including a second silicon oxide layer 20a and a second silicon nitride layer 20b. The first silicon nitride layer 12a, the first silicon oxide layer 12b, the second silicon oxide layer 20a, and the second silicon nitride layer 20b have thicknesses in the ranges indicated in Table 1. In the case of the FFS mode, the active matrix substrate 100 further includes a common electrode 22. In the case of the TN mode or the VA mode, the active matrix substrate 100 does not include a common electrode 22.

The counter substrate 200 typically includes a color filter and a light shielding layer (black matrix). Therefore, the counter substrate 200 may also be referred to as a “color filter substrate”. In the case of the TN mode or the VA mode, the counter substrate 200 includes a counter electrode (common electrode) which is opposed to the pixel electrode 24.

On the surface of each of the active matrix substrate 100 and the counter substrate 200 that is closer to the liquid crystal layer 80, an alignment film is provided. In the case of the FFS mode and the TN mode, horizontal alignment films are to be provided. In the case of the VA mode, vertical alignment films are to be provided.

With reference to FIG. 11 and FIG. 12, a method of producing the liquid crystal display panel 300 will be described.

First, as shown in FIG. 11(a), a mother substrate (hereinafter referred to as a “first mother substrate”) 100M including a plurality of active matrix substrates 100 is provided. A method of providing (producing) the first mother substrate 100M will be described later.

Moreover, in addition to providing the first mother substrate 100A, as shown in FIG. 11(b), a mother substrate (hereinafter referred to as a “second mother substrate”) 200M including a plurality of counter substrates 200 is provided. The counter substrate 200 can be produced by various known methods for producing a color filter substrate.

Next, as shown in FIG. 12(a), the first mother substrate 100M and the second mother substrate 200M are attached together, whereby a mother panel 300M including the plurality of liquid crystal display panels 300 is produced. The first mother substrate 100M and the second mother substrate 200M are adhesively bonded and fixed by a sealing portion (not shown) that is formed so as to surround the display region of the liquid crystal display panel 300.

Thereafter, as shown in FIG. 12(b), the mother panel 300M is cut into the respective liquid crystal display panels 300. The liquid crystal layer 80 between the active matrix substrate 100 and the counter substrate 200 can be formed by one drop filling technique or vacuum injection technique.

Next, with reference to FIG. 13, FIG. 14, and FIG. 15, a method of producing (providing) the first mother substrate 100M will be described.

First, as shown in FIG. 13(a), an electrically-insulative substrate 1M of a size accommodating a plurality of substrates 1 is provided. The electrically-insulative substrate 1M to be provided here is sized so that its longer sides have a length (i.e., a length along the longitudinal direction) of 1800 mm or more.

Next, as shown in FIG. 13(b), a gate electrode 11 is formed on the electrically-insulative substrate 1M for each region, correspondingly to a substrate 1. Scanning lines are also formed at the same time. For example, an electrically conductive film may be deposited on the electrically-insulative substrate 1M, and this electrically conductive film may be patterned into a desired shape through a photolithography process, thus forming the gate electrode 11 and the scanning line. The gate electrode 11 and the scanning line may have a multilayer structure in which a TaN layer with a thickness of 30 nm and a W layer with a thickness of 300 nm are stacked in this order, for example.

Then, a gate insulating layer 12 covering the gate electrode 11 and the scanning line is formed. Specifically, first, as shown in FIG. 13(c), a first silicon nitride layer 12a covering the gate electrode 12 and the scanning line is formed by CVD technique, for example. Thereafter, as shown in FIG. 13(d), a first silicon oxide layer 12b is formed on the first silicon nitride layer 12a by CVD technique, for example.

Next, as shown in FIG. 13(e), on the gate insulating layer 12, an oxide semiconductor layer 13 which is opposed to the gate electrode 11 via the gate insulating layer 12 is formed. For example, an oxide semiconductor film may be deposited on the gate insulating layer 12, and this oxide semiconductor film may be patterned into a desired shape through a photolithography process, thus forming the oxide semiconductor layer 13. The oxide semiconductor layer 13 may be an In—Ga—Zn—O based semiconductor layer with a thickness of 50 nm, for example.

Then, as shown in FIG. 14(a), a source electrode 14 and a drain electrode 15 to be electrically connected to the oxide semiconductor layer 13 are formed. Signal lines are also formed at the same time. For example, an electrically conductive film may be deposited on the oxide semiconductor 13 and the gate insulating layer 12, and this electrically conductive film may be patterned into a desired shape through a photolithography process, thus forming the source electrode 14, the drain electrode 15, and the signal line. The source electrode 14, the drain electrode 15, and the signal line may have a multilayer structure in which a Ti layer with a thickness of 30 nm, an Al layer with a thickness of 200 nm, and a Ti layer with a thickness of 100 nm are stacked in this order, for example.

Next, an inorganic insulating layer 20 covering the oxide semiconductor layer 13, the source electrode 14, the drain electrode 15, and the signal line is formed. Specifically, first, as shown in FIG. 14(b), a second silicon oxide layer 20a covering the oxide semiconductor layer 13 and the like is formed by CVD technique, for example. Thereafter, as shown in FIG. 14(c), a second silicon nitride layer 20b is formed on the second silicon oxide layer 20a by CVD technique, for example. An opening is formed in a region of the inorganic insulating layer 20 to later become a contact hole CH.

Next, as shown in FIG. 15(a), an organic insulating layer 21 is formed on the inorganic insulating layer 20. The organic insulating layer 21 is made of a photosensitive resin material, for example. An opening is made in a region of the organic insulating layer 21 to later become the contact hole CH.

Then, as shown in FIG. 15(b), a common electrode 22 is formed on the organic insulating layer 21. For example, a transparent electrically conductive film may be deposited on the organic insulating layer 21, and this transparent electrically conductive film may be patterned into a desired shape through a photolithography process, thus forming the common electrode 22. The common electrode 22 may be an IZO layer with a thickness of 100 nm, for example.

Next, as shown in FIG. 16(a), a dielectric layer 23 is formed so as to cover the common electrode 22. The dielectric layer 23 may be a silicon nitride layer with a thickness of 100 nm, for example. An opening is made in a region of the dielectric layer 23 to later become the contact hole CH.

Then, as shown in FIG. 16(b), a pixel electrode 24 is formed on the dielectric layer 23. For example, a transparent electrically conductive film may be deposited on the dielectric layer 23, and this transparent electrically conductive film may be patterned into a desired shape through a photolithography process, thus forming the pixel electrode 24. The pixel electrode 14 may be an IZO layer with a thickness of 100 nm, for example. Thereafter, an alignment film is formed across the entire surface so as to cover the pixel electrode 24, whereby an active matrix substrate 100 is obtained.

In the steps described above, the step of forming the first silicon nitride layer 12a, the step of forming the first silicon oxide layer 12b, the step of forming the second silicon oxide layer 20a, and the step of forming the second silicon nitride layer 20b are performed while setting the thicknesses of the first silicon nitride layer 12a, the first silicon oxide layer 12b, the second silicon oxide layer 20a, and the second silicon nitride layer 20b so that du′<0.008 and dv′<0.010. Specifically, variations in chromaticity can be made du′<0.008 and dv′<0.010 by, for example, setting the thicknesses of the first silicon nitride layer 12a, the first silicon oxide layer 12b, the second silicon oxide layer 20a, and the second silicon nitride layer 20b in the ranges indicated in Table 1.

With a production method according to the present embodiment, variations in coloration due to differences in interference colors can be suppressed. Therefore, according to an embodiment of the present invention, while improving the quality of a liquid crystal display panel, upsizing of the mother substrate can be promoted.

[Regarding Oxide Semiconductor]

The oxide semiconductor that is contained in the oxide semiconductor layer 13 may be an amorphous oxide semiconductor film, or a crystalline oxide semiconductor having a crystalline portion(s). Examples of crystalline oxide semiconductors may include polycrystalline oxide semiconductors, microcrystalline oxide semiconductors, and crystalline oxide semiconductors whose c axis is oriented generally perpendicular to the layer plane.

The oxide semiconductor layer 13 may have a multilayer structure of two or more layers. When the oxide semiconductor layer 13 has a multilayer structure, the oxide semiconductor layer 13 may include an amorphous oxide semiconductor layer and a crystalline oxide semiconductor layer. Alternatively, a plurality of crystalline oxide semiconductor layers with different crystal structures may be included. Moreover, a plurality of amorphous oxide semiconductor layers may be included. In the case where the oxide semiconductor layer 13 has a two-layer structure including an upper layer and a lower layer, it is preferable that the oxide semiconductor that is contained in the upper layer has an energy gap which is greater than the energy gap of the oxide semiconductor that is contained in the lower layer. However, when the difference between the energy gaps of these layers is relatively small, the energy gap of the oxide semiconductor of the lower layer may be greater than the energy gap of the oxide semiconductor of the upper layer.

Materials, structures, film formation methods, and the like of amorphous oxide semiconductors and the aforementioned crystalline oxide semiconductors, the construction of an oxide semiconductor layer having a multilayer structure, and the like are described in Japanese Laid-Open Patent Publication No. 2014-007399, for example. The entire disclosure of Japanese Laid-Open Patent Publication No. 2014-007399 is incorporated herein by reference.

The oxide semiconductor layer 13 may contain at least one metallic element among In, Ga, and Zn, for example. In the present embodiment, the oxide semiconductor layer 13 contains an In—Ga—Zn—O type semiconductor (e.g., indium gallium zinc oxide), for example. Herein, the In—Ga—Zn—O type semiconductor is a ternary oxide of In (indium), Ga (gallium), and Zn (zinc). The ratio between In, Ga, and Zn (composition ratio) is not particularly limited, and includes In:Ga:Zn=2:2:1, In:Ga:Zn=1:1:1, In:Ga:Zn=1:1:2, and the like, for example. Such an oxide semiconductor layer 13 may be made of an oxide semiconductor film containing an In—Ga—Zn—O type semiconductor.

The In—Ga—Zn—O type semiconductor may be amorphous or crystalline (i.e., including a crystalline portion(s)). As a crystalline In—Ga—Zn—O type semiconductor, a crystalline In—Ga—Zn—O type semiconductor whose c axis is oriented generally perpendicular to the layer plane is preferable.

Note that the crystal structure of a crystalline In—Ga—Zn—O type semiconductor is disclosed in, for example, Japanese Laid-Open Patent Publication No. 2014-007399, supra, Japanese Laid-Open Patent Publication No. 2012-134475, Japanese Laid-Open Patent Publication No. 2014-209727, and so on. The entire disclosure of Japanese Laid-Open Patent Publication No. 2012-134475 and Japanese Laid-Open Patent Publication No. 2014-209727 is incorporated herein by reference. A TFT having an In—Ga—Zn—O type semiconductor layer has a high mobility (more than 20 times that of an a-Si TFT) and a low leak current (less than 1/100 of that of an a-Si TFT), and is suitably used as a driving TFT (e.g., a TFT that is included in a driving circuit which is provided around a displaying region that includes a plurality of pixels and on the same substrate as the displaying region) or a pixel TFT (a TFT which is provided in a pixel).

The oxide semiconductor layer 13 may contain other oxide semiconductors instead of an In—Ga—Zn—O type semiconductor. For example, it may contain an In—Sn—Zn—O type semiconductor (e.g., In₂O₃—SnO₂—ZnO; InSnZnO). An In—Sn—Zn—O type semiconductor is a ternary oxide of In (indium), Sn (tin), and Zn (zinc). Alternatively, the oxide semiconductor layer 13 may contain an In—Al—Zn—O type semiconductor, an In—Al—Sn—Zn—O type semiconductor, a Zn—O type semiconductor, an In—Zn—O type semiconductor, a Zn—Ti—O type semiconductor, a Cd—Ge—O type semiconductor, a Cd—Pb—O type semiconductor, CdO (cadmium oxide), an Mg—Zn—O type semiconductor, an In—Ga—Sn—O type semiconductor, an In—Ga—O type semiconductor, a Zr—In—Zn—O type semiconductor, an Hf—In—Zn—O type semiconductor, an Al—Ga—Zn—O type semiconductor, a Ga—Zn—O type semiconductor, or the like.

### Embodiment 2

Hereinafter, with reference to the drawings, an active matrix substrate according to the present embodiment will be described. The active matrix substrate according to the present embodiment includes an oxide semiconductor TFT and a crystalline silicon TFT that are formed on the same substrate.

The active matrix substrate has a TFT (pixel TFT) for each pixel. As the pixel TFT, an oxide semiconductor TFT whose active layer is e.g. an In—Ga—Zn—O type semiconductor film is used.

In some cases, a part or a whole of a peripheral driving circuit may be integrally formed on the same substrate as the pixel TFTs. Such an active matrix substrate is referred to as a driver-monolithic active matrix substrate. In a driver-monolithic active matrix substrate, the peripheral driving circuit is to be provided in a region (a non-display region or a frame region) other than the region that contains a plurality of pixels (display region). As the TFTs composing the peripheral driving circuit (circuit TFTs), for example, crystalline silicon TFTs whose active layer is a polycrystalline silicon film may be used. Thus, by using oxide semiconductor TFTs as the pixel TFTs and crystalline silicon TFTs as the circuit TFTs, it becomes possible to reduce power consumption in the displaying region and also reduce the frame region in size.

As the pixel TFTs, the TFTs which have been described above with reference to FIG. 1 can be applied. This point will be discussed later.

Next, a more specific construction for an active matrix substrate according to the present embodiment will be described with reference to the drawings.

FIG. 17 is a schematic plan view showing an exemplary planar structure of an active matrix substrate 700 according to the present embodiment. FIG. 18 is a cross-sectional view of a crystalline silicon TFT (hereinafter referred to as the “first thin film transistor”) 710A and an oxide semiconductor TFT (hereinafter referred to as the “second thin film transistor”) 710B in the active matrix substrate 700.

As shown in FIG. 17, the active matrix substrate 700 has a display region 702 including a plurality of pixels and a region (non-display region) other than the display region 702. The non-display region includes a driving circuit forming region 701 in which driving circuitry is provided. In the driving circuit forming region 701, gate driver circuits 740, a check circuit 770, and the like are provided, for example. In the display region 702, a plurality of gate bus lines (not shown) extending along the row direction and a plurality of source bus lines S extending along the column direction are formed. Although not shown, each pixel is defined by the gate bus lines and the source bus lines S, for example. The gate bus lines are respectively connected to the terminals of the gate driver circuits. The source bus lines S are respectively connected to the terminals of a driver IC 750 that is mounted on the active matrix substrate 700.

As shown in FIG. 18, in the active matrix substrate 700, a second thin film transistor 710B is formed as a pixel TFT for each pixel in the display region 702, whereas first thin film transistors 710A are formed as circuit TFTs in the driving circuit forming region 701.

The active matrix substrate 700 includes a substrate 711, an underlying film 712 formed on the surface of the substrate 711, a first thin film transistor 710A formed on the underlying film 712, and a second thin film transistor 710B formed on the underlying film 712. The first thin film transistor 710A is a crystalline silicon TFT having an active region that mainly contains crystalline silicon. The second thin film transistor 710B is an oxide semiconductor TFT having an active region that mainly contains an oxide semiconductor. The first thin film transistor 710A and the second thin film transistor 710B are fabricated in an integral manner into the substrate 711. As used herein, within the semiconductor layer to become an active layer of a TFT, an “active region” refers to a region where a channel is to be formed.

The first thin film transistor 710A includes a crystalline silicon semiconductor layer (e.g., a low-temperature polysilicon layer) 713 formed on the underlying film 712, a first insulating layer 714 covering the crystalline silicon semiconductor layer 713, and a gate electrode 715A provided on the first insulating layer 714. The portion of the first insulating layer 714 that is located between the crystalline silicon semiconductor layer 713 and the gate electrode 715A functions as a gate insulating film of the first thin film transistor 710A. The crystalline silicon semiconductor layer 713 has a region (active region) 713c in which a channel is to be formed, and a source region 713s and a drain region 713d respectively located on opposite sides of the active region. In this example, a portion of the crystalline silicon semiconductor layer 713 that overlaps the gate electrode 715A via the first insulating layer 714 defines the active region 713c. The first thin film transistor 710A also includes a source electrode 718sA and a drain electrode 718dA which are respectively connected to the source region 713s and the drain region 713d. The source and drain electrodes 718sA and 718dA may be provided on an interlayer insulating film (which herein is a second insulating layer 716) covering the gate electrode 715A and the crystalline silicon semiconductor layer 713, and connected to the crystalline silicon semiconductor layer 713 within contact holes which are formed in the interlayer insulating film.

The second thin film transistor 710B includes a gate electrode 715B provided on the underlying film 712, a second insulating layer 716 covering the gate electrode 715B, and an oxide semiconductor layer 717 on the second insulating layer 716. As shown in the figure, the first insulating layer 714, which is the gate insulating film of the first thin film transistor 710A, may extend to the region where the second thin film transistor 710B is to be formed. In this case, the oxide semiconductor layer 717 may be formed on the first insulating layer 714. A portion of the second insulating layer 716 that is located between the gate electrode 715B and the oxide semiconductor layer 717 functions as a gate insulating film of the second thin film transistor 710B. The oxide semiconductor layer 717 has a region (active region) 717c in which a channel is to be formed, and a source contact region 717s and a drain contact region 717d respectively located on opposite sides of the active region. In this example, a portion of the oxide semiconductor layer 717 that overlaps the gate electrode 715B via the second insulating layer 716 defines the active region 717c. Moreover, the second thin film transistor 710B further includes a source electrode 718sB and a drain electrode 718dB which are respectively connected to the source contact region 717s and the drain contact region 717d. Note that a construction in which no underlying film 712 is formed on the substrate 711 would also be possible.

The thin film transistors 710A and 710B are covered by a passivation film 719 and a planarization film 720. In each second thin film transistor 710B functioning as a pixel TFT, the gate electrode 715B is connected to a gate bus line (not shown), the source electrode 718sB is connected to a source bus line (not shown), and the drain electrode 718dB is connected to the pixel electrode 23. In this example, the drain electrode 718dB is connected to the corresponding pixel electrode 23 within an opening which is formed in the passivation film 719 and the planarization film 720. A video signal is supplied to the source electrode 718sB via the source bus line, and a necessary charge is written to the pixel electrode 23 based on a gate signal from the gate bus line.

As shown in the figure, a transparent conductive layer 721 may be formed as a common electrode on the planarization film 720, and a third insulating layer 722 may be formed between the transparent conductive layer (common electrode) 721 and the pixel electrodes 723. In this case, the pixel electrodes 723 may have slit apertures. The active matrix substrate 700 as such may be applicable to a display device of an FFS mode, for example. An FFS mode is a mode under the lateral field method, in which a pair of electrodes are provided on one substrate and an electric field is applied to liquid crystal molecules in a direction (lateral direction) that is parallel to the substrate plane. In this example, an electric field is created as represented by electric lines of force which go out from the pixel electrode 723, pass through the liquid crystal layer (not shown), and further through the slit apertures in the pixel electrode 723 to emerge on the common electrode 721. This electric field includes a component in a lateral direction to the liquid crystal layer. As a result, an electric field in the lateral direction can be applied to the liquid crystal layer. In the lateral field method, liquid crystal molecules do not erect from the substrate, thus providing an advantage of being able to provide a wider viewing angle than in the vertical field method.

As the second thin film transistor 710B according to the present embodiment, the TFT 10 according to Embodiment 1 which was described above with reference to FIG. 1 can be used. When the TFT 101 in FIG. 1 is applied, the gate electrode 11, the gate insulating layer 12, the oxide semiconductor layer 13, the source electrode 14, and the drain electrode 15 of the TFT 10 correspond to, respectively, the gate electrode 715B, the second insulating layer (gate insulating layer) 716, the oxide semiconductor layer 717, and the source and drain electrodes 718sB and 718dB shown in FIG. 18. Moreover, the inorganic insulating layer 20, the organic insulating layer 21, the common electrode 22, the dielectric layer 23, and the pixel electrode 24 of the active matrix substrate 100 in FIG. 1 correspond to the passivation film 719, the planarization film 720, the transparent electrically conductive layer 721, the third insulating layer 722, and the pixel electrode 723 shown in FIG. 18.

Therefore, the gate insulating layer 716 includes a silicon nitride (first silicon nitride) layer and a silicon oxide layer (first silicon oxide) layer which is provided on the first silicon nitride layer, whereas the passivation film 719 includes a silicon oxide layer (second silicon oxide layer) and a silicon nitride layer (second silicon nitride layer) which is provided on the second silicon oxide layer. Moreover, the first silicon nitride layer, the first silicon oxide layer, the second silicon oxide layer, and the second silicon nitride layer have thicknesses in the ranges indicated in Table 1.

Note that, in the case where the first insulating layer 714 being is a gate insulating film of the first thin film transistor 710A is a silicon nitride layer (hereinafter referred to as a “third silicon nitride layer”), the first silicon nitride layer of the gate insulating layer 716 of the second thin film transistor 710B will be located on this third silicon nitride layer. Therefore, it is preferable that a total of the thickness of the first silicon nitride layer and the thickness of the third silicon nitride layer is within the range indicated in Table 1 (not less than 275 nm and not more than 400 nm).

As a TFT (check TFT) in the check circuit 770 shown in FIG. 17, the thin film transistor 710B, which is an oxide semiconductor TFT, may be used.

Although not shown, the check TFT(s) and the check circuit may be formed in the region where the driver IC 750 shown in FIG. 17 is mounted, for example. In this case, the check TFT is interposed between the driver IC 750 and the substrate 711.

In the example shown in the figure, the first thin film transistor 710A has a top gate structure in which the crystalline silicon semiconductor layer 713 is disposed between the gate electrode 715A and the substrate 711 (the underlying film 712). On the other hand, the second thin film transistor 710B has a bottom gate structure in which the gate electrode 715B is disposed between the oxide semiconductor layer 717 and the substrate 711 (the underlying film 712). By adopting such a structure, when forming the two types of thin film transistors 710A and 710B in an integral manner on the same substrate 711, it is possible to more effectively suppress increase in the number of production steps and the production cost.

The TFT structures of the first thin film transistor 710A and the second thin film transistor 710B are not limited to the above. For example, the thin film transistors 710A and 710B may have the same TFT structure (bottom gate structure). In the case of a bottom gate structure, it may be of the channel-etch type as is the thin film transistor 710B, or of the etchstop type. Moreover, it may be of the bottom-contact type, where the source electrode and the drain electrode would be located below the semiconductor layer.

The second insulating layer 716, which is the gate insulating film of the second thin film transistor 710B, may be allowed to extend to the region where the first thin film transistor 710A is formed, so as to function as an interlayer insulating film covering the gate electrode 715A and the crystalline silicon semiconductor layer 713 of the first thin film transistor 710A.

The gate electrode 715A of the first thin film transistor 710A and the gate electrode 715B of the second thin film transistor 710B may be formed in the same layer. Moreover, the source and drain electrodes 718sA and 718dA of the first thin film transistor 710A and the source and drain electrodes 718sB and 718dB of the second thin film transistor 710B may be formed in the same layer. Being “formed in the same layer” means being formed by using the same film (conductive film). As a result, increase in the number of production steps and the production cost can be suppressed.

### INDUSTRIAL APPLICABILITY

According to an embodiment of the present invention, it is possible to suppress variations in coloration when producing a liquid crystal display panel that includes an active matrix substrate which includes: oxide semiconductor TFTs; and a gate insulating layer and an inorganic insulating layer each having a multilayer structure.

### REFERENCE SIGNS LIST

1 substrate

10 TFT (thin film transistor)

11 gate electrode

12 gate insulating layer

12a first silicon nitride layer

12b first silicon oxide layer

13 oxide semiconductor layer

14 source electrode

15 drain electrode

20 inorganic insulating layer (passivation film)

20a second silicon oxide layer

20b second silicon nitride layer

21 organic insulating layer (planarization film)

22 common electrode

23 dielectric layer

24 pixel electrode

80 liquid crystal layer

100 active matrix substrate

100M first mother substrate

200 counter substrate

200M second mother substrate

300 liquid crystal display panel

300M mother panel

CH contact hole

1. An active matrix substrate comprising:
a substrate;
a plurality of thin film transistors supported on the substrate; and
an inorganic insulating layer which covers the plurality of thin film transistors, wherein,
each of the plurality of thin film transistors includes
a gate electrode provided on the substrate,
a gate insulating layer which covers the gate electrode,
an oxide semiconductor layer being provided on the gate insulating layer and opposed to the gate electrode via the gate insulating layer, and
a source electrode and a drain electrode which are electrically connected to the oxide semiconductor layer;
the gate insulating layer includes a first silicon nitride layer and a first silicon oxide layer which is provided on the first silicon nitride layer;
the inorganic insulating layer includes a second silicon oxide layer and a second silicon nitride layer which is provided on the second silicon oxide layer;
the first silicon nitride layer has a thickness which is not less than 275 nm and not more than 400 nm;
the first silicon oxide layer has a thickness which is not less than 20 nm and not more than 80 nm;
the second silicon oxide layer has a thickness which is not less than 200 nm and not more than 300 nm; and
the second silicon nitride layer has a thickness which is not less than 100 nm and not more than 200 nm.

2. The active matrix substrate of claim 1, wherein the oxide semiconductor layer comprises an In—Ga—Zn—O based semiconductor.

3. The active matrix substrate of claim 2, wherein the In—Ga—Zn—O based semiconductor includes a crystalline portion.

4. The active matrix substrate of claim 1, comprising a further thin film transistor that includes a crystalline silicon semiconductor layer as an active layer.

5. The active matrix substrate of claim 4, wherein the further thin film transistor includes:
the crystalline silicon semiconductor layer provided on the substrate;
a further gate insulating layer which covers the crystalline silicon semiconductor layer;
a further gate electrode being provided on the further gate insulating layer and opposed to the crystalline silicon semiconductor layer via the further gate insulating layer; and
a further source electrode and a further drain electrode which are electrically connected to the crystalline silicon semiconductor layer.

6. The active matrix substrate of claim 5, wherein,
the further gate electrode is covered by the gate insulating layer;
the further gate insulating layer includes a third silicon nitride layer; and
a total of a thickness of the first silicon nitride layer of the gate insulating layer and a thickness of the third silicon nitride layer of the further gate insulating layer is not less than 275 nm and not more than 400 nm.

7. A liquid crystal display panel comprising:
the active matrix substrate of claim 1 any of claims 1 to 6;
a counter substrate opposed to the active matrix substrate; and
a liquid crystal layer provided between the active matrix substrate and the counter substrate.

8. A method of producing a liquid crystal display panel that includes an active matrix substrate having a substrate and a plurality of thin film transistors supported on the substrate, a counter substrate opposed to the active matrix substrate, and a liquid crystal layer provided between the active matrix substrate and the counter substrate, the method comprising:
step (A) of providing a first mother substrate including a plurality of said active matrix substrates;
step (B) of providing a second mother substrate including a plurality of said counter substrates;
step (C) of producing a mother panel by attaching together the first mother substrate and the second mother substrate, the mother panel including a plurality of said liquid crystal display panels; and
step (D) of obtaining the liquid crystal display panel by cutting apart the mother panel, wherein,
step (A) of providing the first mother substrate comprises
step (a) of providing an electrically-insulative substrate of a size accommodating a plurality of said substrates,
step (b) of forming gate electrodes on the electrically-insulative substrate, for each region corresponding to the substrate,
step (c) of forming a gate insulating layer which covers the gate electrodes,
step (d) of forming an oxide semiconductor layer on the gate insulating layer, the oxide semiconductor layer being opposed to the gate electrodes via the gate insulating layer,
step (e) of forming source electrodes and drain electrodes which are electrically connected to the oxide semiconductor layer, and
step (f) of forming an inorganic insulating layer which covers the oxide semiconductor layer, the source electrodes, and the drain electrodes;
step (c) comprises
step (c-1) of forming a first silicon nitride layer which covers the gate electrodes, and
step (c-2) of forming a first silicon oxide layer on the first silicon nitride layer;
step (f) comprises
step (f-1) of forming a second silicon oxide layer which covers the oxide semiconductor layer, the source electrodes, and the drain electrodes, and
step (f-2) of forming a second silicon nitride layer on the second silicon oxide layer;
the electrically-insulative substrate to be provided in step (a) is sized so that a length thereof along a longitudinal direction is 1800 mm or more; and,
when variation in chromaticity (u′, v′) within a plane of the first mother substrate that is caused by an interference of light associated with the first silicon nitride layer, the first silicon oxide layer, the second silicon oxide layer, and the second silicon nitride layer is expressed by a difference du′ between a largest u′ and a smallest u′ and a difference dv′ between a largest v′ and a smallest v′,
steps (c-1), (c-2), (f-1), and (f-2) are performed while setting thicknesses of the first silicon nitride layer, the first silicon oxide layer, the second silicon oxide layer, and the second silicon nitride layer so that du′<0.008 and dv′<0.010.

9. The method of producing of a liquid crystal display panel of claim 8, wherein,
in step (c-1), the first silicon nitride layer is formed with a thickness which is not less than 275 nm and not more than 400 nm;
in step (c-2), the first silicon oxide layer is formed with a thickness which is not less than 20 nm and not more than 80 nm;
in step (f-1), the second silicon oxide layer is formed with a thickness which is not less than 200 nm and not more than 300 nm; and
in step (f-2), the second silicon nitride layer is formed with a thickness which is not less than 100 nm and not more than 200 nm.

10. The method of producing of a liquid crystal display panel of claim 8, wherein the oxide semiconductor layer comprises an In—Ga—Zn—O based semiconductor.

11. The method of producing of a liquid crystal display panel of claim 10, wherein the In—Ga—Zn—O based semiconductor includes a crystalline portion.
